(19) United States
(12) Patent Application Publication
(10) Pub. No.: US 2010/0085690 A1
(43) Pub. Date: Apr. 8, 2010

(54) DEVICE HOUSING WITH DECORATIVE PATTERN AND METHOD OF MANUFACTURING SAME

(75) Inventors: YI ZOU, Shenzhen City (CN); CHIN-JEN LIN, Shindian (TW); FA-HONG ZENG, Shenzhen City (CN); XIAO-JUN ZOU, Shenzhen City (CN); XIAO-MING ZHU, Shenzhen City (CN); JIE TANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/538,261

(22) Filed: Aug. 10, 2009

(30) Foreign Application Priority Data
Oct. 8, 2008 (CN) 200810304778.6

(51) Int. Cl. H05K 7/00; B23P 11/00

(52) U.S. Cl. 361/679.01; 29/428

(57) ABSTRACT

A device housing is provided. The device housing includes a base device housing, a decorative pattern area, and a plurality of metallic balls. The base device housing defines a plurality of receiving holes. The decorative pattern area is formed in the exterior surface of the base device housing. The metallic balls are positioned in the receiving holes and located inside or outside the decorative pattern area. A method of manufacturing the device housing is also provided.

### BACKGROUND

1. Technical Field

The present disclosure relates to a device housing with a decorative pattern and a method for manufacturing the device housing.

2. Description of Related Art

Device housings for portable electronic devices are often decorated with patterns to improve aesthetic appearance. Typically, the patterns are directly printed/coated on the exterior surface of the device housings. However, it can be difficult and costly to achieve a desired three-dimensional appearance.

Therefore, there is room for improvement within the art.

### BRIEF DESCRIPTION OF THE DRAWING

Many aspects of the disclosed device housing and method of manufacturing the same can be better understood with reference to the flowering drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a plan view of a device housing with a decorative pattern according to an exemplary embodiment.

FIG. 2 is a cross-section of the device housing shown in FIG. 1, taken along line II-II of FIG. 1.

### DETAILED DESCRIPTION

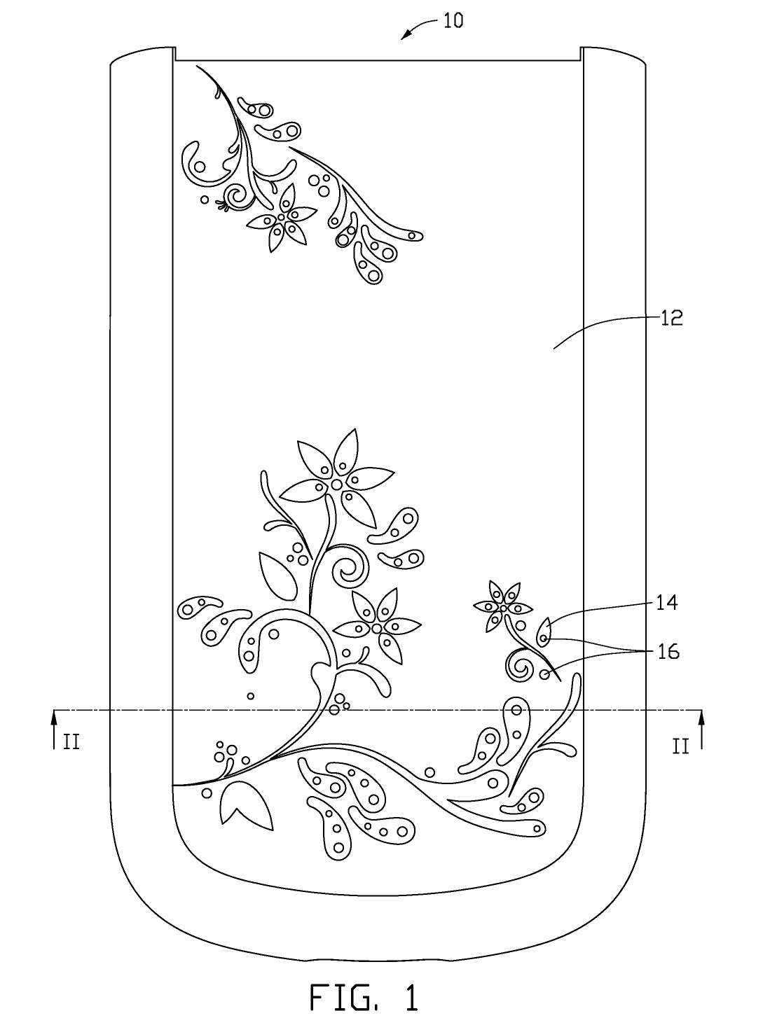

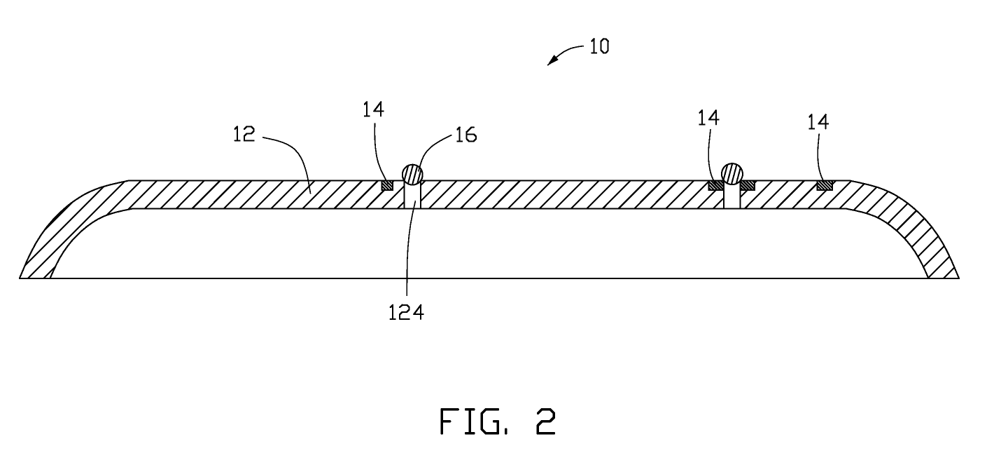

FIGS. 1 and 2 show an exemplary device housing 10 including a base device housing 12, a decorative pattern area 14, and a plurality of metallic balls 16.

The base device housing 12 can be a metallic device housing or a plastic device housing. The decorative pattern area 14, depicting, for example, flowers, is directly formed in the exterior surface of the base device housing 12.

The base device housing 12 defines a plurality of receiving holes 124. The receiving holes 124 correspond to and receive the metallic balls 16 by, for example, the metallic balls being hot-melted/adhered therein. The diameter of each receiving hole 124 can be about two thirds that of the corresponding metallic ball 16, thus, the respective metallic ball 16 partially protrudes from the corresponding receiving hole 124, further through the decorative pattern area 14 if located therein.

The decorative pattern area 14 can be filled by resin or ink of a predetermined color. The metallic balls 16 can be coated or electroplated with other predetermined colors. Due to the embedding relationship of the decorative pattern area 14 and the metallic balls 16 and their variant color arrangement, the device housing 10 can provide a three-dimensional decorative appearance.

In a method of manufacturing a device housing with a decorative pattern, as shown in FIG. 1, a base device housing 12 with the receiving holes 124 is provided for example, by insert molding. The exterior surface of the base device housing 12 can be recessed and further filled by resin or ink to form the decorative pattern area 14. The decorative pattern area 14 is then dried, by, for example hot-drying. The receiving holes 124 are located inside or outside the decorative pattern area 14. The metallic balls can be positioned in the receiving holes 124.

Understandably, the embedding of the metallic balls can be implemented before formation of the decorative pattern area 14. The recessing of the base device housing 12 can be previously finished by the insert molding of the base device housing 12.

It is to be understood, however, that even through numerous characteristics and advantages of exemplary embodiments have been set forth in the foregoing description, together with details of the structure and function of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A device housing with a decorative pattern, comprising:
a base device housing defining a plurality of receiving holes;
a decorative pattern area formed in the exterior surface of the base device housing; and
a plurality of metallic balls corresponding to the plurality of receiving holes, the metallic balls positioned in the receiving holes.

2. The device housing with a decorative pattern as claimed in claim 1, wherein the decorative pattern area is recessed in the exterior surface of the base device housing and filled by resin or ink of a predetermined color.

3. The device housing with a decorative pattern as claimed in claim 2, wherein the decorative pattern area has a flower appearance.

4. The device housing with a decorative pattern as claimed in claim 2, wherein the metallic balls are of a different predetermined color from the decorative pattern.

5. The device housing with a decorative pattern as claimed in claim 1, wherein the metallic balls partially protrude from their respective receiving holes.

6. The device housing with a decorative pattern as claimed in claim 5, wherein the diameter of each receiving hole can be about two thirds that of the corresponding metallic ball.

7. The device housing with a decorative pattern as claimed in claim 5, wherein the metallic balls protrude through the decorative pattern area when located in the decorative pattern area.

8. The device housing with a decorative pattern as claimed in claim 1, wherein the base device housing is a metallic device housing or plastic device housing.

9. A method for manufacturing a device housing with a decorative pattern, comprising:
providing a base device housing;
defining a plurality of receiving holes;
recessing a predetermined pattern in the base device housing;
forming a decorative pattern area in the base device housing;
positioning the metallic balls in the receiving holes.

10. The method as claimed in claim 9, wherein the metallic balls are hot-melted or adhered into the receiving holes.

11. The method as claimed in claim 9, wherein the base device housing is insert molded with the receiving holes.

12. The method as claimed in claim 11, wherein the recessing of the base device housing is implemented during the insert molding.

13. The method as claimed in claim 9, wherein the decorative pattern area is formed by the recessing and a further filling thereof with resin or ink.

14. The method as claimed in claim 13, wherein after formation of the decorative pattern area, the decorative pattern area is dried.

15. The method as claimed in claim 13, wherein the resin or ink is of a predetermined color, and the metallic balls 16 are coated or electroplated with a different predetermined color than the decorative area.
